(19) United States
(12) Patent Application Publication
(10) Pub. No.: US 2023/0129921 A1
(43) Pub. Date: Apr. 27, 2023

(54) SEMICONDUCTOR DEVICES AND MANUFACTURING METHODS FOR THE SAME

(71) Applicant: Samsung Electronics Co., Ltd., Suwon-si (KR)

(72) Inventors: Sunju KIM, Yongin-si (KR); Namsu KIM, Hwaseong-si (KR); Jinwon JEONG, Hwaseong-si (KR)

(73) Assignee: Samsung Electronics Co., Ltd., Suwon-si (KR)

(21) Appl. No.: 17/965,860

(22) Filed: Oct. 14, 2022

(30) Foreign Application Priority Data
Oct. 25, 2021 (KR) 10-2021-0143034

(51) Int. Cl. H01L 27/108

(52) U.S. Cl. CPC H01L 27/10897; H01L 27/10814; H01L 27/10823; H01L 27/10894

(57) ABSTRACT

A semiconductor device including a substrate having a cell array area, a peripheral circuit area, and a boundary area therebetween, gate electrodes in the cell array area and in a plurality of word line trenches extending to an inside of the substrate, a device isolation layer in the peripheral circuit area of the substrate and defining active areas, and a boundary structure in the boundary area and in a boundary trench extending to the inside of the substrate may be provided. The boundary structure may include a buried insulating layer on an inner wall of the boundary trench, an insulating liner on the buried insulating layer, and a gap-fill insulating layer filling an inside of the boundary trench on the insulating liner, and an upper surface of the insulating liner may be at a lower level than an upper surface of a corresponding one of the active area.

### CROSS-REFERENCE TO RELATED APPLICATION

This application is based on and claims priority under 35 U.S.C. § 119 to Korean Patent Application No. 10-2021-0143034, filed on Oct. 25, 2021, in the Korean Intellectual Property Office, the disclosure of which is incorporated by reference herein in its entirety.

### BACKGROUND

The inventive concepts relate to semiconductor devices and/or manufacturing methods of the same, and more particularly, to semiconductor devices including a cell capacitor and/or manufacturing methods of the semiconductor device.

A size of an individual fine circuit pattern for embodying a semiconductor device decreases according to downscaling of the semiconductor device. Also, because of the size reduction of the fine circuit pattern, defects, etc. may occur during a process of forming word line trenches having small widths in a substrate.

### SUMMARY

Some example embodiments of the inventive concepts provide semiconductor devices capable of preventing discontinuity defects in word lines.

Some example embodiments of the inventive concepts provide manufacturing methods of a semiconductor device capable of preventing discontinuity defects in word lines.

According to an aspect of the inventive concepts, a semiconductor device includes a substrate including a cell array area, a peripheral circuit area, and a boundary area between the cell array area and the peripheral circuit area, a plurality of gate electrodes being in the cell array area of the substrate and in a plurality of word line trenches that extend to an inside of the substrate, a device isolation layer in the peripheral circuit area of the substrate and defining a plurality of active areas, and a boundary structure in the boundary area of the substrate and in a boundary trench that extends to the inside of the substrate, wherein the boundary structure includes a buried insulating layer on an inner wall of the boundary trench, an insulating liner on the buried insulating layer, and a gap-fill insulating layer on the insulating liner and filling an inside of the boundary trench, and an upper surface of the insulating liner is at a lower level than an upper surface of a corresponding one of the active areas.

According to another aspect of the inventive concepts, a semiconductor device includes a substrate including a cell array area, a peripheral circuit area, and a boundary area between the cell array area and the peripheral circuit area, a device isolation layer in the peripheral circuit area of the substrate and defining a plurality of active areas, a boundary structure in the boundary area of the substrate and being in a boundary trench that extends to an inside of the substrate, the boundary structure including a buried insulating layer on an inner wall of the boundary trench, an insulating liner on the buried insulating layer, and a gap-fill insulating layer on the insulating liner and filling an inside of the boundary trench, and a plurality of gate electrodes in the cell array area of the substrate, being in a plurality of word line trenches that extend to the inside of the substrate, the plurality of gate electrodes having end portions each being on the buried insulating layer and the insulating liner, wherein an upper surface of the insulating liner is at a lower level than an upper surface of the active area.

According to another aspect of the inventive concepts, a semiconductor device includes a substrate including a cell array area, a peripheral circuit area, and a boundary area between the cell array area and the peripheral circuit area, a device isolation layer in the peripheral circuit area of the substrate and defining a plurality of active areas, a boundary structure in the boundary area of the substrate and being in a boundary trench that extends to an inside of the substrate, the boundary structure including a buried insulating layer on an inner wall of the boundary trench, an insulating liner on the buried insulating layer, and a gap-fill insulating layer on the insulating liner and filling an inside of the boundary trench, and a plurality of gate electrodes in the cell array area of the substrate and being in a plurality of word line trenches that extend to the inside of the substrate, the plurality of gate electrodes having end portions each being on the buried insulating layer and the insulating liner, wherein an upper surface of the buried insulating layer is at a lower level than an upper surface of the active area and does not cover a corner region of a corresponding one of the active area.

### BRIEF DESCRIPTION OF THE DRAWINGS

Example embodiments of the inventive concepts will be more clearly understood from the following detailed description taken in conjunction with the accompanying drawings in which:

FIG. 1 illustrates a layout of a semiconductor device according to an example embodiment:

FIG. 2 illustrates an enlarged layout of a region A of FIG. 1;

FIG. 3 is a cross-sectional view of a semiconductor device taken along line B1-B1′ of FIG. 2;

FIG. 4 is a cross-sectional view of a semiconductor device taken along line B2-B2′ of FIG. 2;

FIG. 5 is an enlarged cross-sectional view illustrating a region CX1 of FIG. 3;

FIG. 6 is an enlarged cross-sectional view illustrating a region CX2 of FIG. 4; and

FIGS. 7A to 20B are cross-sectional views of a manufacturing method of a semiconductor device, according to an example embodiment. In detail, FIGS. 7A, 8A. 9A. 10A, 15A, 17, 18A, 19A, and 20A are cross-sectional views corresponding to cross-sections of a semiconductor device taken along line B1-B1′ of FIG. 2, FIGS. 7B, 88, 9B, 10B, 15B, 16A, 18B. 19B, and 208 are cross-sectional views corresponding to cross-sections of a semiconductor device taken along line B2-B2′ of FIG. 2, and FIGS. 7C, 8C, 9C, 10C, 11 to 14, 15C, and 16B are cross-sectional views corresponding to an enlarged view of a region CX1 of FIG. 3.

### DETAILED DESCRIPTION

Hereinafter, one or more example embodiments of the inventive concepts will be described in detail with reference to the attached drawings.

While the term “same,” “equal” or “identical” is used in description of example embodiments, it should be understood that some imprecisions may exist. Thus, when one element is referred to as being the same as another element, it should be understood that an element or a value is the same as another element within a desired manufacturing or operational tolerance range (e.g., ±10%).

When the terms “about” or “substantially” are used in this specification in connection with a numerical value, it is intended that the associated numerical value includes a manufacturing or operational tolerance (e.g., ±10%) around the stated numerical value. Moreover, when the words “about” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes.

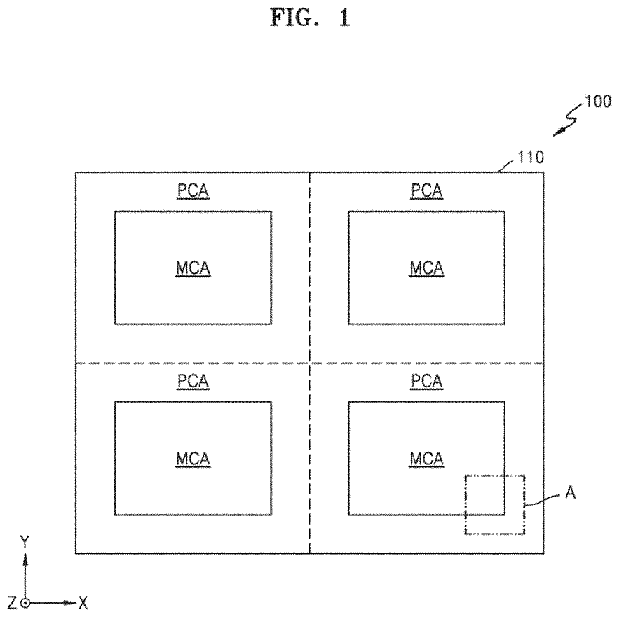

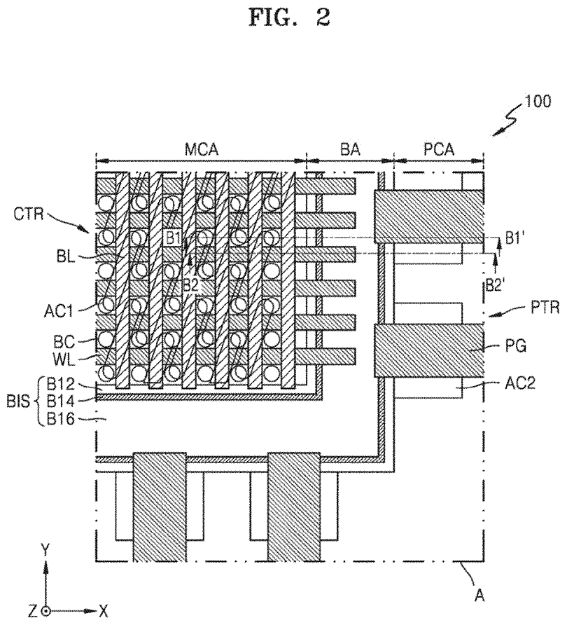

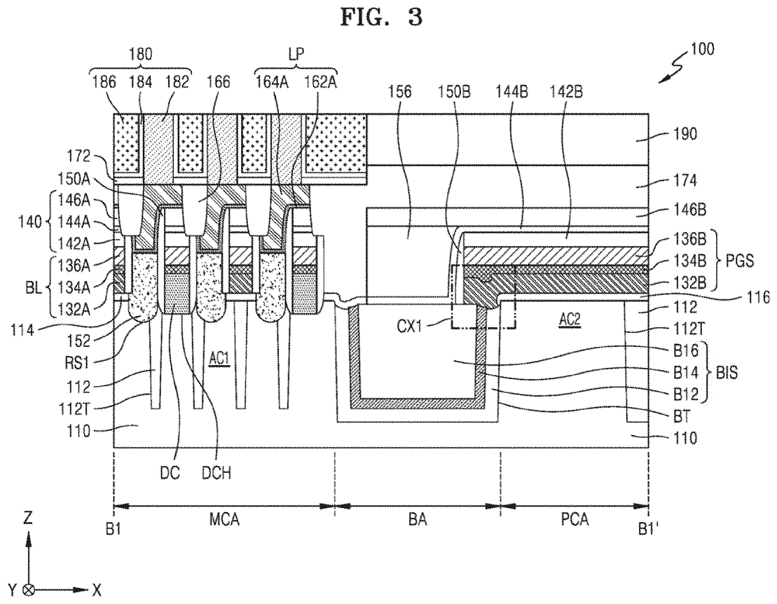

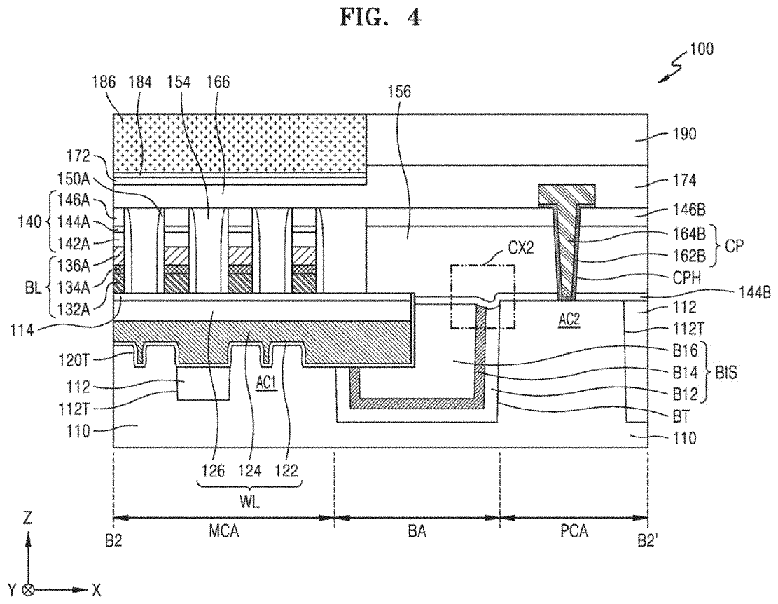

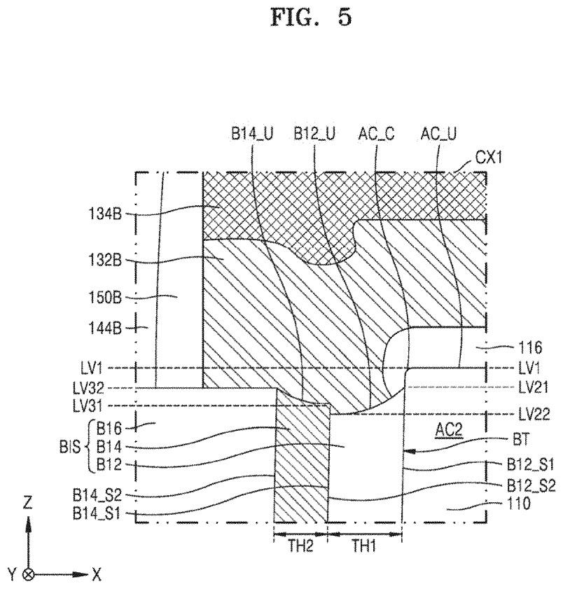

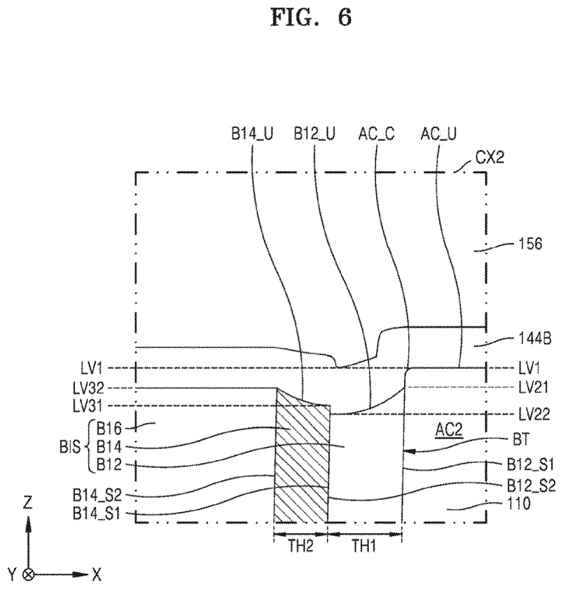

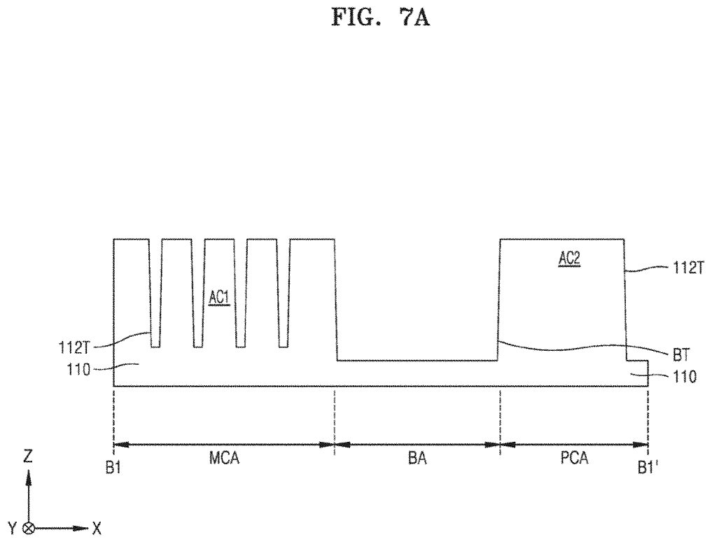

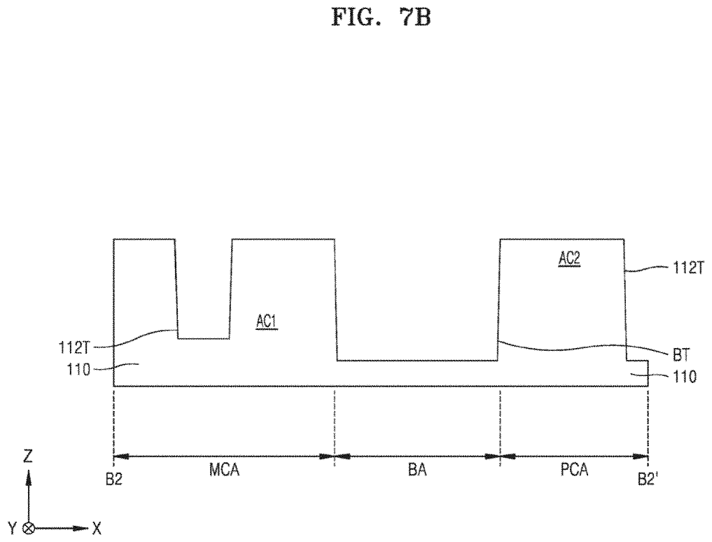

FIG. 1 illustrates a layout of a semiconductor device 100 according to an example embodiment. FIG. 2 illustrates an enlarged layout of a region A of FIG. 1. FIG. 3 is a cross-sectional view of the semiconductor device 100 taken along line B1-B1′ of FIG. 2. FIG. 4 is a cross-sectional view of the semiconductor device 100 taken along line B2-B2′ of FIG. 2. FIG. 5 is an enlarged cross-sectional view illustrating a region CX1 of FIG. 3. FIG. 6 is an enlarged cross-sectional view illustrating a region CX2 of FIG. 4.

Referring to FIGS. 1 to 6, the semiconductor device 100 may include a substrate 110 including a cell array area MCA and a peripheral circuit area PCA. The cell array area MCA may be a memory cell area of a Dynamic Random Access Memory (DRAM) device, and the peripheral circuit area PCA may be a core area or a peripheral circuit area of the DRAM device. For example, the cell array area MCA may include a cell transistor CTR and a capacitor structure 180 connected thereto, and the peripheral circuit area PCA may include a peripheral circuit transistor PTR configured to transmit signals and/or power to the cell transistor CTR included in the cell array area MCA. In some example embodiments, the peripheral circuit transistor PTR may configure various circuits such as a command decoder, a control logic, an address buffer, a row decoder, a column decoder, a sense amplifier, and a data input/output circuit.

Device isolation trenches 112T may be formed in the substrate 110, and a device isolation layer 112 may be formed in the device isolation trenches 112T. A plurality of first active areas AC1 may be defined by the device isolation layer 112 in the substrate 110 in the cell array area MCA, and a plurality of second active areas AC2 may be defined in the substrate 110 in the peripheral circuit area PCA.

A boundary trench BT may be formed in a boundary area BA between the cell array area MCA and the peripheral circuit area PCA, and a boundary structure BIS may be formed in the boundary trench BT. In a plan view, the boundary trench BT may be arranged to surround four sides of the cell array area MCA. The boundary structure BIS may include a buried insulating layer B12, an insulating liner B14, and a gap-fill insulating layer B16 arranged in the boundary trench BT.

The buried insulating layer B12 may be conformally arranged on an inner wall of the boundary trench BT and may have a first thickness TH1 in a first horizontal direction X. The first thickness TH1 may range from about 1 nm to about 200 nm, but is not limited thereto. In some example embodiments, the buried insulating layer B12 may include silicon oxide. For example, the buried insulating layer B12 may include silicon oxide formed through an atomic layer deposition (ALD) process, a chemical vapor deposition (CVD) process, a plasma-enhanced CVD (PECVD) process, or a low-pressure CVD (LPCVD) process.

In some example embodiments, the buried insulating layer B12 may include a first sidewall B12_S1 contacting a portion of the substrate 110 (e.g., the second active area AC2) that is exposed to the boundary trench BT, and a second sidewall B12_S2 opposite to the first sidewall B12_S1 and contacting the insulating liner B14. For example, an upper surface B12_U of the buried insulating layer B12 may be at a lower vertical level than an upper surface AC_U of the second active area AC2, and thus, a corner region AC_C of the second active area AC2 may not be covered by the buried insulating layer B12. Here, the corner region AC_C of the second active area AC2 may indicate an upper end portion of the second active area AC2 arranged on a boundary between the boundary area BA and the peripheral circuit area PCA.

The insulating liner B14 may be conformally arranged on the inner wall of the boundary trench BT (e.g., on the buried insulating layer B12) and may have a second thickness TH2 in the first horizontal direction X. The second thickness TH2 may range from about 10 nm to about 200 nm, but is not limited thereto. In some example embodiments, the insulating liner B14 may include silicon nitride. For example, the insulating liner B14 may include silicon nitride formed through an ALD process, a CVD process, a PECVD process, or an LPCVD process.

The insulating liner B14 may include a first sidewall B14_S1 contacting the buried insulating layer B12, and a second sidewall B14_S2 opposite to the first sidewall B14_S1 and contacting the gap-fill insulating layer B16. An upper surface B14_U of the insulating liner B14 may be at a lower level than an upper surface of the substrate 110. For example, the upper surface B14_U of the insulating liner B14 may be at a lower vertical level than the upper surface AC_U of the second active area AC2.

The gap-fill insulating layer B16 may fill the inside of the boundary trench BT (e.g., a remaining space of the boundary trench BT defined by the insulating liner B14). In some example embodiments, the gap-fill insulating layer B16 may include silicon oxide such as tonen silazene (TOSZ), undoped silicate glass (USG), boro-phospho-silicate glass (BPSG), phosphosilicate glass (PSG), flowable oxide (FOX), plasma enhanced deposition material of tetra-ethyl-ortho-silicate (PE-TEOS), or fluoride silicate glass (FSG).

In some example embodiments, the upper surface B12_U of the buried insulating layer B12 may have an inclined upper-surface level that gradually decreases in a direction away from the substrate 110 (e.g., in a direction laterally away from the second active area AC2), whereas the upper surface B14_U of the insulating liner B14 may have an inclined upper-surface level that gradually increases in the direction away from the substrate 110.

As illustrated in FIG. 3, for example, the upper surface of the substrate 110, that is, the upper surface AC_U of the second active area AC2, may be at a first vertical level LV1, and a portion of the upper surface B12_U that is adjacent to the first sidewall B12_S1 of the buried insulating layer B12 may be at a second vertical level LV21 that is lower than the first vertical level LV1, and a portion of the upper surface B12_U that is adjacent to the second sidewall B12_S2 of the buried insulating layer B12 may be at a third vertical level LV22 that is lower than the second vertical level LV21.

A portion of the upper surface B14_U that is adjacent to the first sidewall B14_S1 of the insulating liner B14 may be at a fourth vertical level LV31 that is lower than the first vertical level LV1, and a portion of the upper surface B14_U that is adjacent to the second sidewall B14_S2 of the insulating liner B14 may be at a fifth vertical level LV32 that is higher than the fourth vertical level LV31. The upper surface B12_U of the buried insulating layer B12 and the upper surface B14_U of the insulating liner B14 may entirely be at a lower vertical level than the upper surface of the substrate 110, that is, the upper surface AC_U of the second active area AC2.

In some example embodiments, a level difference between the upper surface AC_U of the second active area AC2 and a portion of the upper surface B14_U that is adjacent to the second sidewall B14_S2 of the insulating liner B14 (e.g., a difference between the first vertical level LV1 and the fifth vertical level LV32) may be greater than about 0 nm and less than or equal to about 10 nm. That is, the portion of the upper surface B14_U that is adjacent to the second sidewall B14_S2 of the insulating liner B14 may be at a vertical level that is lower than that of the upper surface AC_U of the second active area AC2 by about 0 nm to about 10 nm.

As the upper surface B14_U of the insulating liner B14 is arranged at a lower level than the upper surface AC_U of the second active area AC2, an oxide layer remaining on the second active area AC2 may be completely removed, and the corner region AC_C and the upper surface AC_U of the second active area AC2 may be completely exposed during a process of forming a gate dielectric layer 116 on the second active area AC2. Accordingly, the gate dielectric layer 116 having excellent crystal quality may be formed on the second active area AC2.

In the cell array area MCA, the first active areas AC1 may be respectively arranged to have long axes in a diagonal direction with respect to the first horizontal direction X and a second horizontal direction Y. Word lines WL may extend in parallel with each other in the first horizontal direction X by crossing the first active areas AC1. On the word lines WL, the hit lines BL may extend in parallel with each other in the second horizontal direction Y. The bit lines BL may be connected to the first active areas AC1 through direct contacts DC, respectively.

Buried contacts BC may be formed between two bit lines BL, which are adjacent to each other from among the bit lines BL. The buried contacts BC may be arranged in a row in the first horizontal direction X and the second horizontal direction Y. Landing pads LP may be formed on the buried contacts BC. The buried contacts BC and the landing pads LP may function as connectors for connecting a lower electrode 182 of the capacitor structure 180, which is formed on the bit lines BL, to the first active area AC1. The landing pads LP may overlap portions of the buried contacts BC, respectively.

The substrate 110 may include silicon, for example, single crystalline silicon, polycrystalline silicon, or amorphous silicon. In other example embodiments, the substrate 110 may include at least one selected from among germanium (Ge), silicon-germanium (SiGe), silicon carbide (SiC), gallium arsenide (GaAs), indium arsenide (InAs), and indium phosphide (InP). In some example embodiments, the substrate 110 may include a conductive area, for example, a well or a structure doped with impurities. The device isolation layer 112 may include an oxide film, a nitride film, or a combination thereof.

In the cell array area MCA, a plurality of word lines trenches 120T extending in a first direction (the X direction) are formed in the substrate 110, and a plurality of gate dielectric films 122, a plurality of gate electrodes 124, and a plurality of capping insulating films 126 are formed in the word lines trenches 120T. The gate electrodes 124 may correspond to the word lines WL illustrated in FIG. 1, respectively. The gate dielectric films 122 may each include a silicon oxide film, a silicon nitride film, a silicon oxynitride film, an oxide/nitride/oxide (ONO) film, or a high-k dielectric film having a greater dielectric constant than the silicon oxide film. The gate electrodes 124 may each include titanium (Ti), titanium nitride (TiN), tantalum (Ta), tantalum nitride (TaN), tungsten (W), tungsten nitride (WN), titanium silicon nitride (TiSiN), tungsten silicon nitride (WSiN), or a combination thereof. The capping insulating films 126 each may include a silicon oxide film, a silicon nitride film, a silicon oxynitride film, or a combination thereof.

The word line trenches 120T may extend to the inside of the boundary area BA from the cell array area MCA, and an end portion of each word line trench 120T may vertically overlap the boundary structure BIS in the boundary area BA. The end portion of each word line trench 120T may be arranged on the buried insulating layer B12 and the insulating liner B14, and a portion of the word line trench 120T arranged on the buried insulating layer B12 and the insulating liner B14 may have a relatively flat bottom surface.

A buffer film 114 may be formed on the substrate 110 in the cell array area MCA. The buffer film 114 may include an oxide film, a nitride film, or a combination thereof.

The direct contacts DC may be formed in a plurality of direct contact holes DCH in the substrate 110. The direct contacts DC may be connected to the first active areas AC1, respectively. The direct contacts DC may each include doped polysilicon. For example, the direct contacts DC each may include polysilicon including n-type impurities such as phosphorous (P), arsenic (As), bismuth (Bi), and antimony (Sb) at a relatively high concentration.

The bit lines BL may extend, in the second horizontal direction Y, on the substrate 110 and the direct contacts DC. The bit lines BL may be connected to the first active areas A1 through the direct contacts DC, respectively. The bit lines BL each may include a lower conductive pattern 132A, an intermediate conductive pattern 134A, and an upper conductive pattern 136A that are sequentially stacked on the substrate 110. The lower conductive pattern 132A may include doped polysilicon. The intermediate conductive pattern 134A and the upper conductive pattern 136A each may include TiN, TiSiN, W, tungsten silicide, or a combination thereof. In some example embodiments, the intermediate conductive pattern 134A may include TiN, TiSiN, or a combination thereof, and the upper conductive pattern 136A may include W.

The bit lines BL may be covered by a plurality of insulating capping structures 140, respectively. The insulating capping structures 140 may extend on the bit lines BL in the second horizontal direction Y. The insulating capping structures 140 each may include a lower capping pattern 142A, a protective layer pattern 144A, and an upper capping pattern 146A.

Spacers 150A may be arranged on both sidewalls of each bit line BL. The spacers 150A may extend on both sidewalls of the bit lines BL in the second horizontal direction Y, and a portion of the spacer 150A may extend to the inside of the direction contact hole DCH and thus may cover both sidewalls of the direct contact DC. FIG. 3 illustrates that the spacer 150A is a single material layer, but in other example embodiments, the spacer 150A may have a stack configuration including a plurality of spacer layers (not illustrated), and at least one of the spacer layers may be an air spacer.

The direct contact DC may be formed in the direct contact hole DCH in the substrate 110 and may extend to a level higher than the level of the upper surface of the substrate 110. For example, the upper surface of the direct contact DC may be at the same level as an upper surface of the lower conductive pattern 132A and may contact a bottom surface of the intermediate conductive pattern 134A. Also, a bottom surface of the direct contact DC may be at a lower level than the upper surface of the substrate 110.

Insulating fences 154 and conductive plugs 152 may be arranged between the bit lines BL, respectively, in a row in the second horizontal direction Y. The insulating fences 154 may be arranged on the capping insulating film 126 on upper portions of the word line trenches 120T, and the conductive plugs 152 may extend, in the vertical direction (the Z direction), from a recess space RS1 formed in the substrate 110. Sidewalls of respective conductive plugs 152 may be insulated from each other by the insulating fences 154 in the second horizontal direction Y. The conductive plugs 152 may form the buried contacts BC of FIG. 1.

The landing pads LP may be formed on the conductive plugs 152. Although not illustrated, a metal silicide film (not illustrated) may be further arranged between the conductive plugs 152 and the landing pads LP. The metal silicide film may include cobalt silicide, nickel silicide, or manganese silicide. Each landing pad LP may include a conductive barrier film 162A and a landing pad conductive layer 164A. The conductive barrier film 162A may include Ti. TiN, or a combination thereof. The landing pad conductive layer 164A may include metal, metal nitride, conductive polysilicon, or a combination thereof. For example, the landing pad conductive layer 164A may include W. In the plan view, the land pads LP may have island patterns. The landing pads LP may be electrically insulated from each other by insulating patterns 166 surrounding the periphery of the landing pads LP. The insulating pattern 166 may include at least one of silicon nitride, silicon oxide, and silicon oxynitride.

In the cell array area MCA, a first etch stop layer 172 may be arranged on the landing pad LP and the insulating pattern 166. The capacitor structure 180 may be arranged on the first etch stop layer 172. The capacitor structure 180 may include lower electrodes 182, a capacitor dielectric layer 184, and an upper electrode 186.

The lower electrodes 182 may penetrate the first etch stop layer 172 and extend on the landing pads LP in the vertical direction Z. Bottom portions of the lower electrodes 182 may be connected to the landing pads LP via the first etch stop layer 172. The capacitor dielectric layer 184 may be arranged on the lower electrodes 182. The upper electrode 186 may be arranged on the capacitor dielectric layer 184 to cover the lower electrodes 182.

In some example embodiments, the capacitor dielectric layer 184 may include at least one of zirconium oxide, hafnium oxide, titanium oxide, niobium oxide, tantalum oxide, yttrium oxide, strontium titanium oxide, barium strontium titanium oxide, scandium oxide, or lanthanum oxide. The lower electrode 182 and the upper electrode 186 may include at least one selected from among metal (e.g., ruthenium (Ru), Ti, Ta, niobium (Nb), iridium (Ir), molybdenum (Mo), or W), conductive metal nitride (e.g., TiN, TaN, niobium nitride (NbN), molybdenum nitride (MoN), or WN), and conductive metal oxide (e.g., iridium oxide (IrO₂), ruthenium oxide (RuO₂), or strontium ruthenium oxide (SrRuO₃)).

In some example embodiments, the lower electrodes 182 may each have a pillar shape extending in the vertical direction Z and a circular horizontal cross-section. However, the shape of the horizontal cross-section of the lower electrode 182 is not limited thereto, and the lower electrodes 182 may have horizontal cross-sections having an oval shape or various polygonal or round polygonal shapes such as a square, a round square, a rhombus, and trapezoid. Also, FIG. 3 illustrates that the lower electrodes 182 have pillar shapes having circular horizontal cross-sections over the total height, but in other example embodiments, the lower electrodes 182 may have cylindrical shapes having closed bottoms.

In the peripheral circuit area PCA, the peripheral circuit transistor PTR may be arranged in the second active area AC2. The peripheral circuit transistor PTR may include a gate dielectric layer 116, a peripheral circuit gate electrode PGS, and a gate capping pattern 142B that are sequentially stacked in the second active area AC2.

The gate dielectric layer 116 may include at least one selected from among a silicon oxide film, a silicon nitride film, a silicon oxynitride film, ONO, and a high-k dielectric film having a greater dielectric constant than the silicon oxide film. The peripheral circuit gate electrode PGS may include a lower conductive pattern 132B, an intermediate conductive pattern 134B, and an upper conductive pattern 136B. Materials for forming the lower conductive pattern 132B, the intermediate conductive pattern 134B, and the upper conductive pattern 136B may be the same as the materials for forming the lower conductive pattern 132A, the intermediate conductive pattern 134A, and the upper conductive pattern 136A included in the bit line BL in the cell array area MCA, respectively. The gate capping pattern 142B may include a silicon nitride film.

Both sidewalls of the peripheral circuit gate electrode PGS and the gate capping pattern 142B may be covered by the insulating spacer 150B. The insulating spacer 150B may include an oxide film, a nitride film, or a combination thereof. The peripheral circuit transistor PTR and the insulating spacer 150B may be covered by a protective layer 144B, and a first interlayer insulating film 156 may be arranged on the protective layer 144B such that a gap between two adjacent peripheral circuit transistors PTR may be filled. The first interlayer insulating film 156 may have an upper surface arranged coplanar with an upper surface of the protective layer 144B arranged on an upper surface of the peripheral circuit transistor PTR. A capping insulating layer 146B may be arranged on the first interlayer insulating film 156 and the protective layer 144B.

In the peripheral circuit area PCA, a contact plug CP may be formed in a contact hole CPH vertically penetrating the first interlayer insulating film 156 and the capping insulating layer 146B. The contact plug CP may include a conductive barrier film 162B and a landing pad conductive layer 164B, similarly to the landing pads LP formed in the cell array area MCA. A metal silicide film (not illustrated) may be arranged between the second active area AC2 and the contact plug CP.

A second etch stop layer 174 covering the contact plug CP may be arranged on the capping insulating layer 146B. A second interlayer insulating layer 190 covering the capacitor structure 180 may be arranged on the second etch stop layer 174.

The boundary structure BIS may be arranged in the boundary area BA between the cell array area MCA and the peripheral circuit area PCA. For example, a level difference (e.g., a level difference due to a U-shaped recess in the upper surface of the insulating liner B14) may be generated on an upper surface of the boundary structure BIS, which has a relatively large width. In this case, a portion of a mask pattern M10 for forming the word line trench 120f may remain on the insulating liner B14, and thus, unetched regions, where a height of the word line trench 120T is less than a target height, may be generated and the word lines WL may not be continuously connected in some portions because of the unetched regions.

According to some example embodiments, however, the buried insulating layer B12, the insulating liner B14, and the gap-fill insulating layer B16 may have a relatively small upper-surface level difference because of a double strip process. Therefore, in the process of forming the word line trenches 120T, the generation of unetched regions and the discontinuity defects in the word lines WL may be reduced or prevented.

Moreover, the upper surfaces of the buried insulating layer B12 and the insulating liner B14 may be at a lower vertical level than the upper surface of the substrate 110 because of the double strip process, and the upper surface AC_U and the corner region AC_C of the second active area AC2 may not be covered by the buried insulating layer B12 and the insulating liner B14. Therefore, the gate dielectric layer 116 having improved crystal quality may be formed on the second active area AC2 in a process of forming the gate dielectric layer 116. The semiconductor device 100 may have great reliability.

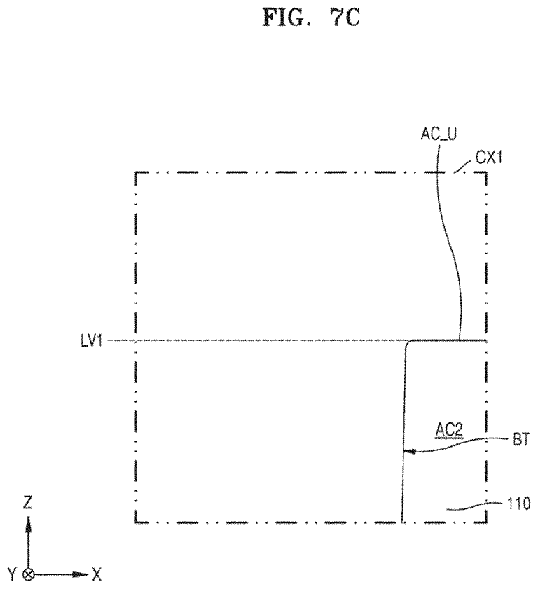

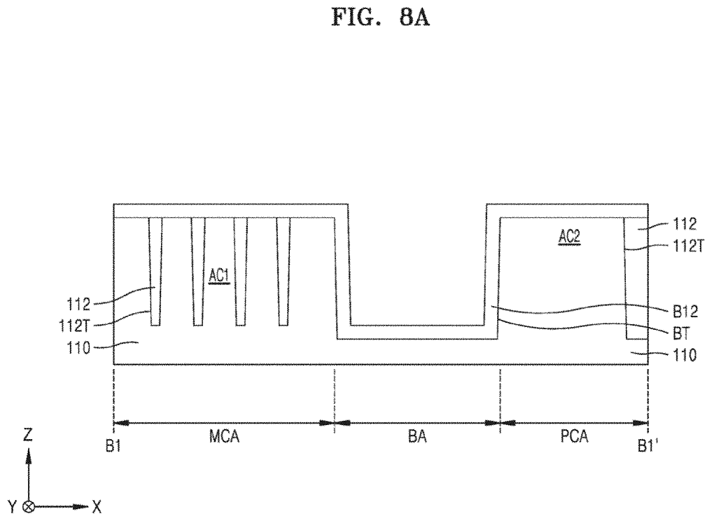

FIGS. 7A to 20B are cross-sectional views of a manufacturing method of the semiconductor device 100, according to an example embodiment. In detail, FIGS. 7A, 8A, 9A, 10A, 15A, 17, 18A, 19A, and 20A are cross-sectional views corresponding to cross-sections of the semiconductor device 100 taken along line B1-B1′ of FIG. 2. FIGS. 7B, 8B, 9B, 10B, 15B, 16A, 18B, 19B, and 20B are cross-sectional views corresponding to cross-sections of the semiconductor device 100 taken along line B2-B2′ of FIG. 2, and FIGS. 7C, 8C, 9C, 10C, 11 to 14, 15C, and 16B are cross-sectional views corresponding to an enlarged view of a region CX1 of FIG. 3. The same reference symbols in FIGS. 1 to 6 and 7A to 20B denote the same elements.

Referring to FIGS. 7A to 7C, the device isolation trenches 112T may be formed in the cell array area MCA and the peripheral circuit area PCA of the substrate 110, and the boundary trench BT may be formed in the boundary area BA of the substrate 110.

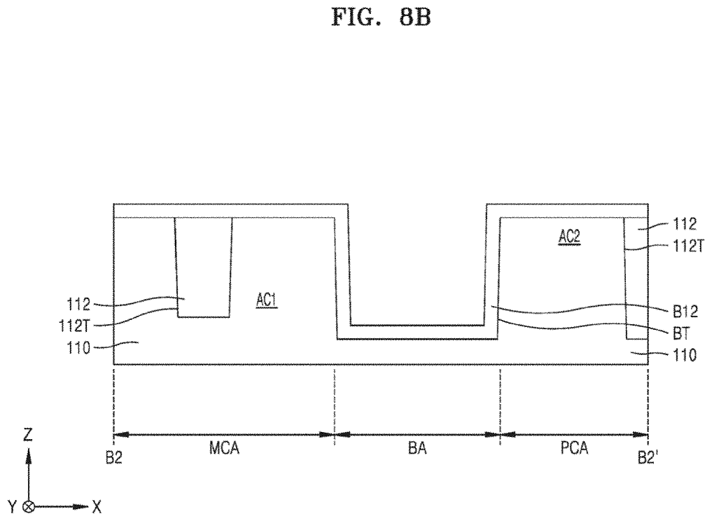

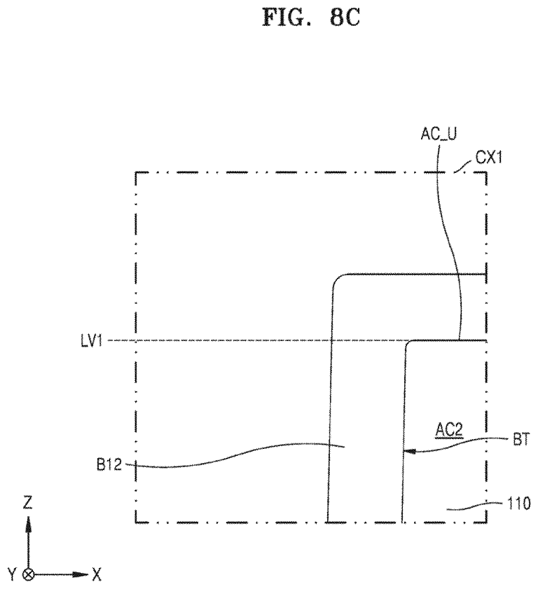

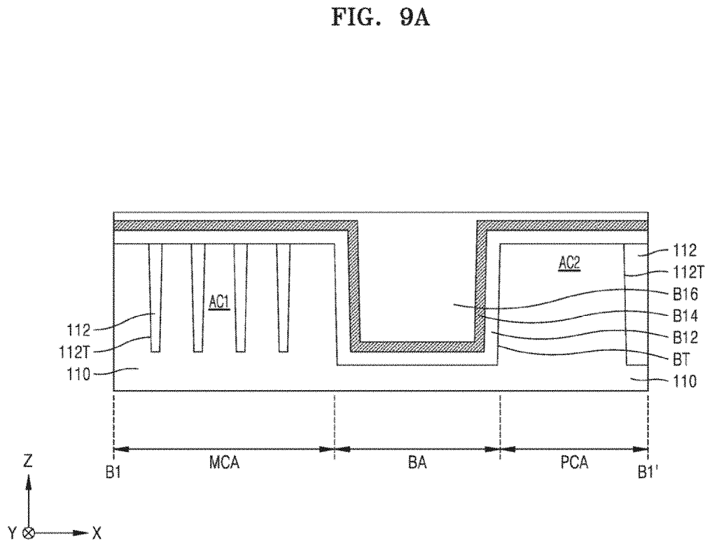

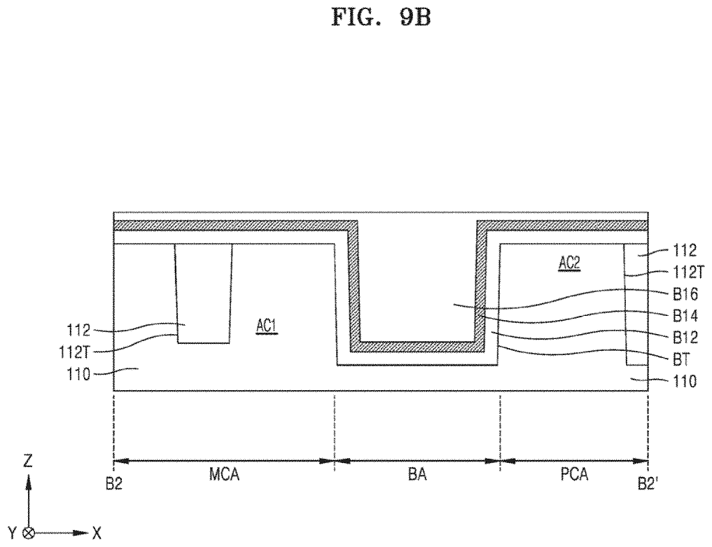

Referring to FIGS. 8A to 8C, the device isolation layer 112 filling the device isolation trenches 112T may be formed in the cell array area MCA and the peripheral circuit area PCA. As the device isolation layer 112 is formed, the first active areas AC1 are defined in the cell array area MCA of the substrate 110, and the second active areas AC2 are defined in the peripheral circuit area PCA.

In some example embodiments, the device isolation layer 112 may include silicon oxide, silicon nitride, silicon oxynitride, or a combination thereof. In some example embodiments, the device isolation layer 112 may have a double-layer structure including a silicon oxide layer and a silicon nitride layer, but is not limited thereto.

The buried insulating layer B12 may be formed on the inner wall of the boundary trench BT. The buried insulating layer B12 may be formed through an ALD process, a CVD process, a PECVD process, an LPCVD process, or the like.

In some example embodiments, a process of forming the buried insulating layer B12 may be performed in the same operation as some operations of a process of forming the device isolation layer 112, but one or more example embodiments are not limited thereto. In other example embodiments, the process of forming the buried insulating layer B12 may be separately performed after the process of forming the device isolation layer 112.

The buried insulating layer B12 may be conformally formed on the sidewall and the bottom surface of the boundary trench BT and the upper surface of the substrate 110 to cover, for example, the upper surface AC_U of the second active area AC2.

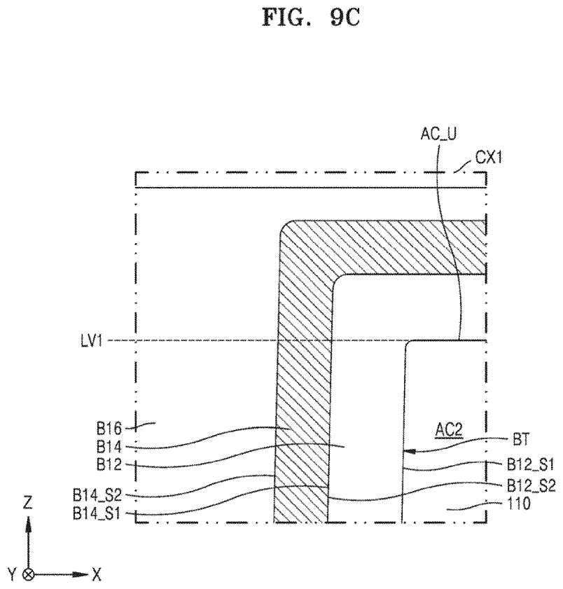

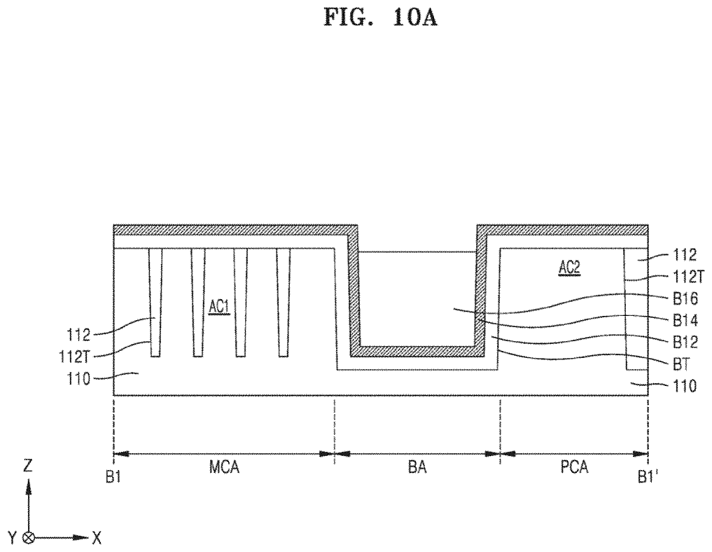

Referring to FIGS. 9A to 9C, the insulating liner B14 and the gap-fill insulating layer B16 may be sequentially formed on the inner wall of the boundary trench BT.

In some example embodiments, the insulating liner B14 may be formed using silicon nitride through an ALD process, a CVD process, a PECVD process, an LPCVD process, or the like. The insulating liner B14 may be conformally formed on the sidewall and the bottom surface of the boundary trench BT and the upper surface of the substrate 110 to cover, for example, the upper surface AC_U of the second active area AC2.

The gap-till insulating layer B16 on the insulating liner B14 may fill the inside of the boundary trench BT. The gap-fill insulating layer B16 may have a thickness that is sufficient to completely fill the remaining portions inside of the boundary trench BT.

In some example embodiments, the gap-fill insulating layer B16 may include silicon oxide such as TOSZ, USG, BPSG, PSG, FOX, PE-TEOS, or FSG.

As illustrated in FIG. 9C, the buried insulating layer B12 may include the first sidewall B12_S1 contacting a portion of the substrate 110 (e.g., the second active area AC2) that is exposed to the boundary trench BT, and the second sidewall B12_S2 opposite to the first sidewall B12_S1 and contacting the insulating liner B14. The insulating liner B14 may include the first sidewall B14_S1 contacting the buried insulating layer B12 and the second sidewall B14_S2 opposite to the first sidewall B14_S1 and contacting the gap-fill insulating layer B16.

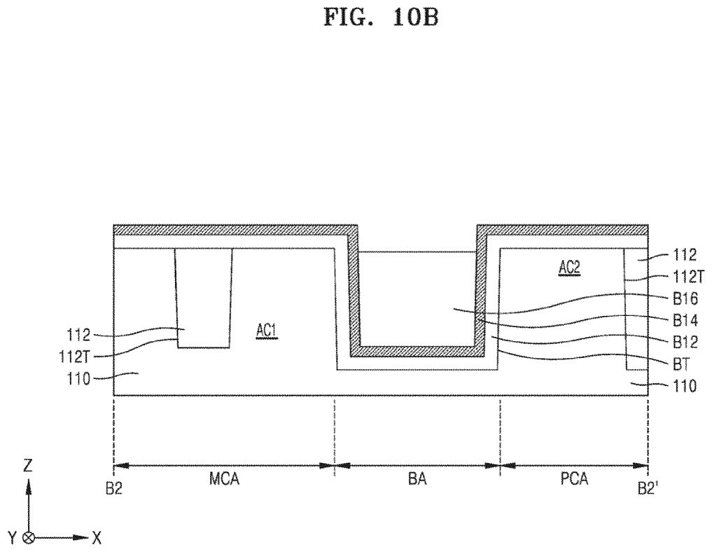

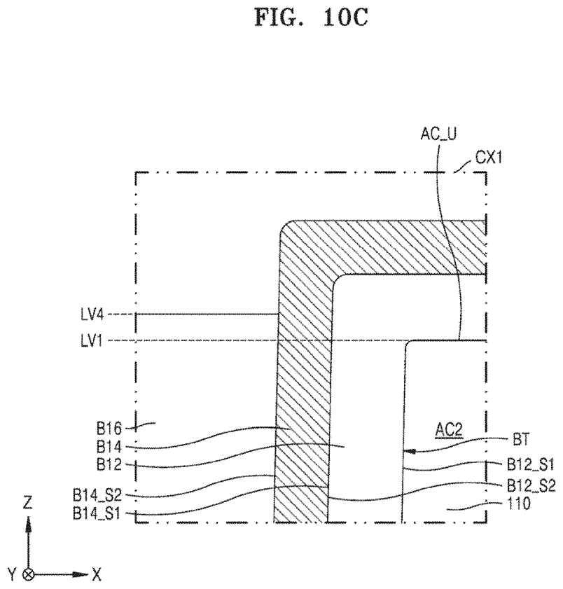

Referring to FIGS. 10A to 10C, a portion of the gap-fill insulating layer B16 that is on the upper surface of the substrate 110 may be removed during a first wet-etching process. Thus, the upper surface of the gap-fill insulating layer B16 may be at a lower level than the upper surface of the insulating liner B14, and for example, the upper-surface level LV4 of the gap-fill insulating layer B16 may be higher than a level of the upper-surface of the substrate 110 (e.g., the first vertical level LV1), but may be lower than the level of the upper surface of the buried insulating layer B12.

In some example embodiments, the first wet-etching process may be an etching process using an etchant including ammonium fluoride (NH₄F), hydrofluoric acid (HF), and water, but is not limited thereto.

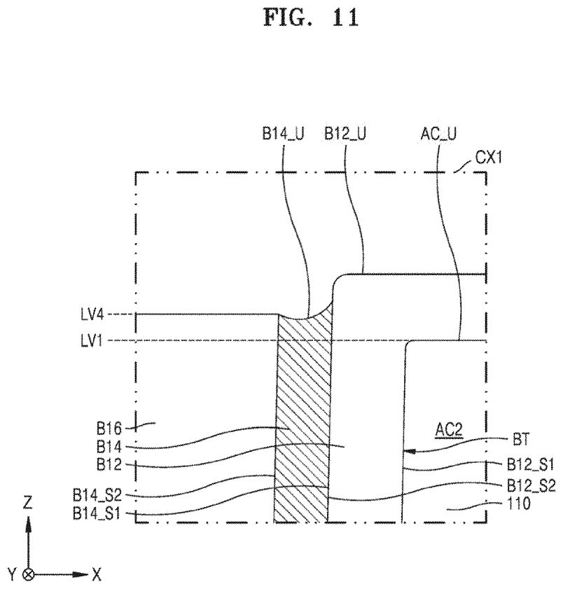

Referring to FIG. 11, a portion of the insulating liner B14 that is on the upper surface of the substrate 110 may be removed by performing a first strip process on an upper portion of the insulating liner B14. As the portion of the insulating liner B14 is removed, the upper surface B12_U of the buried insulating layer B12 may be exposed again.

In some example embodiments, the first strip process may be an etching process using an etchant including phosphoric acid, nitric acid, acetic acid, or a combination thereof, but is not limited thereto.

In a process of decreasing or lowering the height of the insulating liner B14 according to the first strip process, a portion of the insulating liner B14 that is adjacent to the gap-fill insulating layer B16 may be exposed relatively more to an etching atmosphere, and accordingly, the upper surface B14_U of the insulating liner B14 may have an inclined shape in which the portion of the upper surface B14_U of the insulating liner B14 that is adjacent to the gap-fill insulating layer B16 is at a lower level than a portion of the insulating liner B14 that is adjacent to the buried insulating layer B12.

In some example embodiments, the upper surface B14_U of the insulating liner B14 may be at a similar level to the upper-surface level LV4 of the gap-fill insulating layer B16. The upper surface B14_U of the insulating liner B14 may be at a higher level than the upper surface of the substrate 110.

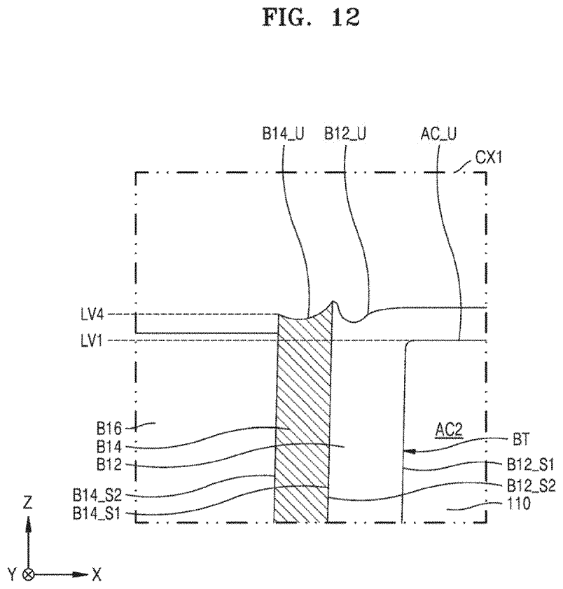

Referring to FIG. 12, some portions of the buried insulating layer B12 and the gap-fill insulating layer B16 arranged on the upper surface of the substrate 110 may be removed during a second wet-etching process.

In some example embodiments, the second wet-etching process may be an etching process using an etchant including NH₄F. HF, and water, but is not limited thereto.

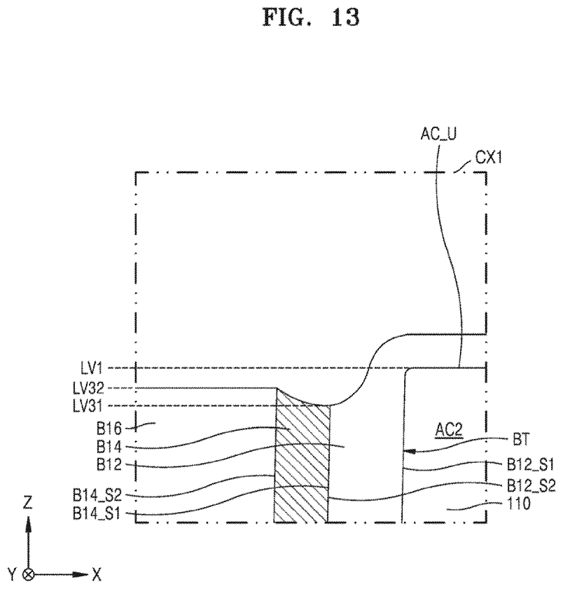

Referring to FIG. 13, the upper-surface level of the insulating liner B14 may be lowered by performing a second strip process on an upper portion of the insulating liner B14.

In some example embodiments, the second strip process may be an etching process using an etchant including phosphoric acid, nitric acid, acetic acid, or a combination thereof, but is not limited thereto.

In some example embodiments, after the second strip process, the insulating liner B14 may have an upper surface that is at a lower level than the upper-surface level LV1 of the substrate 110. For example, the upper surface B14_U of the insulating liner B14 may have an inclined upper-surface level that gradually increases in a direction away from the substrate 110 (e.g., in a direction laterally away from the second active area AC2). A portion of the upper surface B14_U of the insulating liner B14 that is adjacent to the first sidewall B14_S1 of the insulating liner B14 may be at the fourth vertical level LV31 that is lower than the first vertical level LV1, and a portion of the upper surface B14_U of the insulating liner B14 that is adjacent to the second sidewall B14_S2 of the insulating liner B14 may be at the fifth vertical level LV32 that is higher than the fourth vertical level LV31.

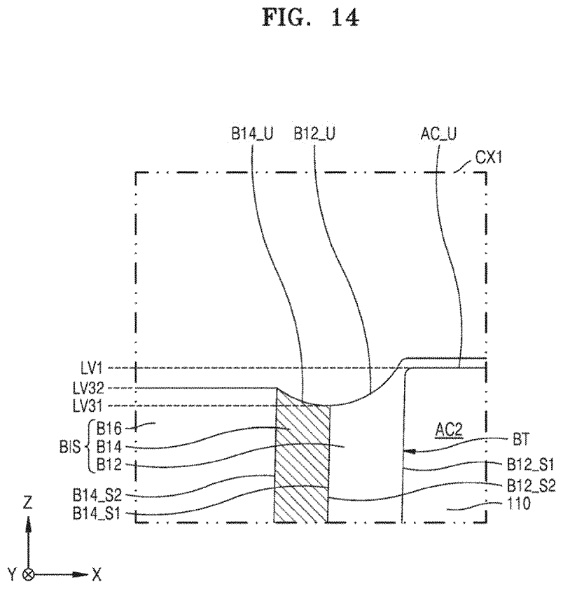

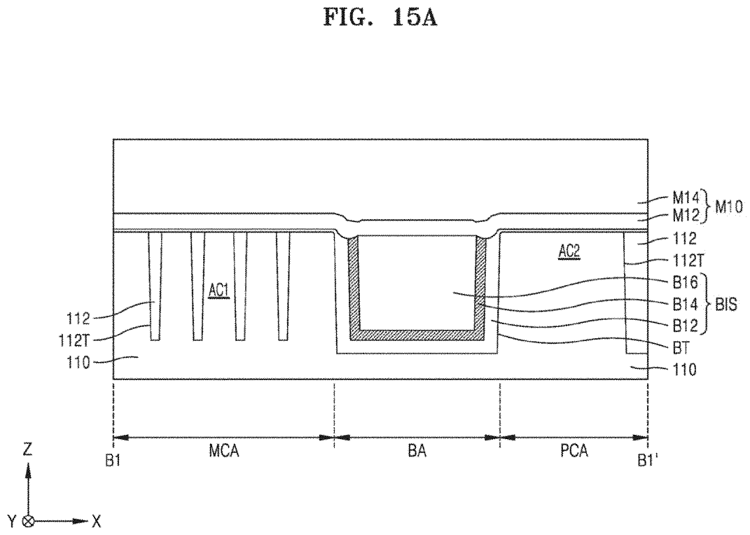

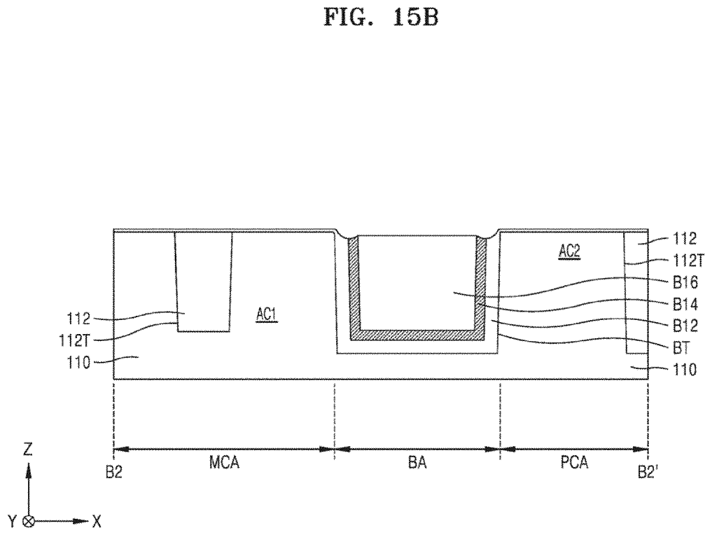

Referring to FIG. 14, an upper portion of the buried insulating layer B12 may be removed by performing a planarization process on the buried insulating layer B12.

In some example embodiments, after the planarization process, a level difference between the upper surface B12_U of the buried insulating layer B12 and the upper surface B14_U of the insulating liner B14 may decrease. For example, the upper surface B12_U of the buried insulating layer B12 and the upper surface B14_U of the insulating liner B14 may have a gentle U-shaped profile continuously connected.

In some example embodiments, the level difference between the upper surface B12_U of the buried insulating layer B12 and the upper surface B14_U of the insulating liner B14 may range from about 0 Å to about 100 Å. For example, a portion of the upper surface B12_U of the buried insulating layer B12 that is on the upper surface of the substrate 110 may be at a higher level than a point of the upper surface B14_U of the insulating liner B14 that is adjacent to the first sidewall B14_S1 of the insulating liner B14, by about 0 Å to about 100 Å.

In some example embodiments, the upper surface B12_U of the buried insulating layer B12 and the upper surface B414_U of the insulating liner B14 may be gently connected to each other without a steep inclination or a dramatic level difference by sequentially performing the first wet-etching process, the first strip process, the second wet-etching process, the second strip process, and the planarization process described above. In addition, the upper surface B14_U of the insulating liner B14 may be entirely at a lower level than the upper surface of the substrate 110 or the upper surface AC_U of the second active area AC2.

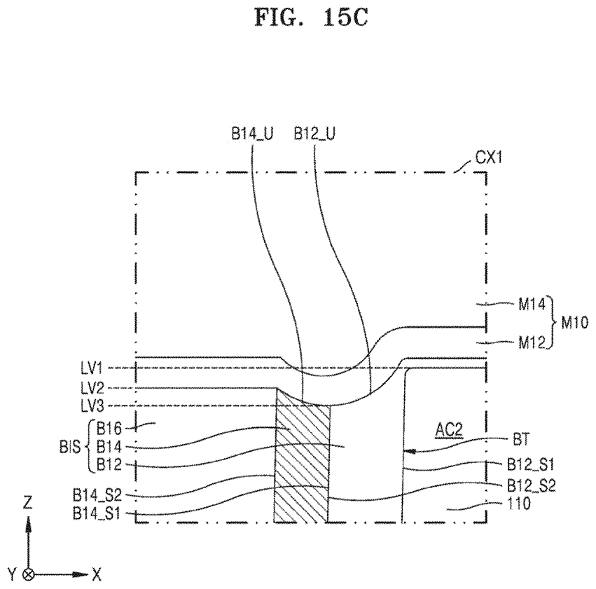

Referring to FIGS. 15A to 15C, the mask pattern M10 may be formed on the substrate 110, and a portion of the cell array area MCA of the substrate 110 may be removed by using the mask pattern M10 as an etch mask, thereby forming the word line trenches 120T.

The word line trench 120T may be arranged to extend to a portion of the boundary area BA from the cell array area MCA.

For example, the mask pattern M10 for forming the word line trench 120T may be formed according to double patterning technology (DPT) or quadruple patterning technology (QPT), but one or more example embodiments are not limited thereto.

The mask pattern M10 for forming the word line trench 120T may have a multilayered structure including a plurality of material layers. For example, the mask pattern M10 may have a stack structure including a first material layer M12 and a second material layer M14. In some example embodiments, the first material layer M12 may include silicon oxide, and the second material layer M14 may include an amorphous carbon layer (ACL), but one or more example embodiments are not limited thereto. For example, the first material layer M12 may have a relatively small thickness, and the second material layer M14 may have a relatively great thickness.

According to some example embodiments, because the upper surface B12_U of the buried insulating layer B12 and the upper surface B14_U of the insulating liner B14 may be gently connected to each other without a steep inclination or a dramatic level difference, the first material layer M12 and the second material layer M14 of the mask pattern M10 may also have a relatively uniform upper-surface level and/or a uniform width over the total height. Also, the word line trench 120T formed using the mask pattern M10 may have a uniform width over the total height without discontinuous sections or unetched regions.

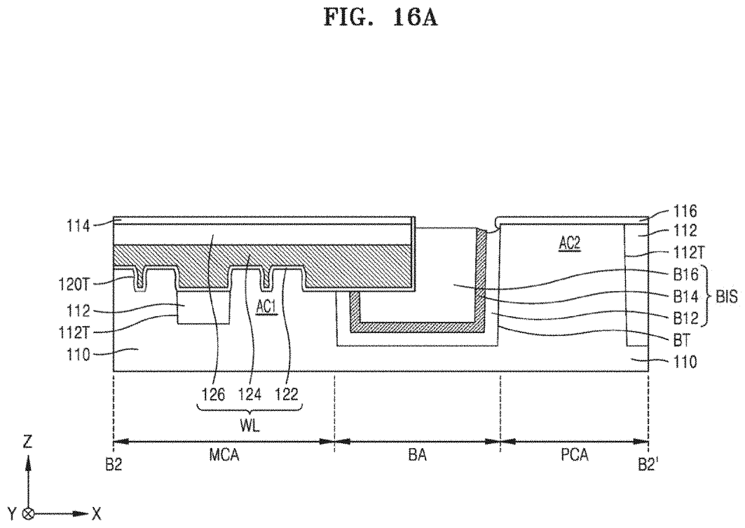

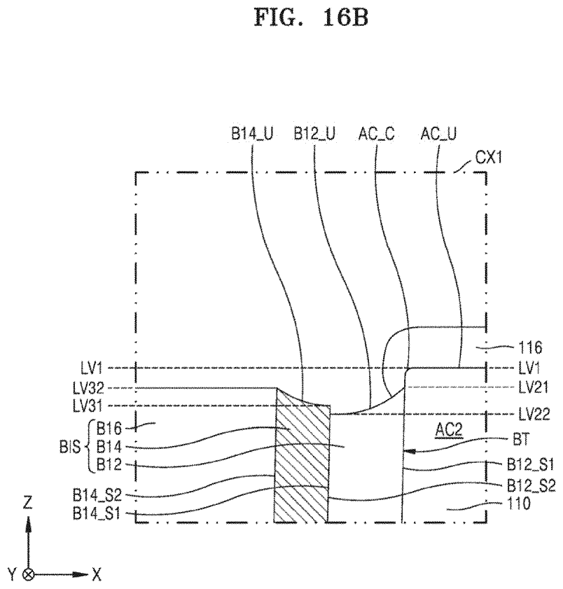

Referring to FIGS. 16A and 16B, the gate dielectric film 122, the gate electrode 124, and the capping insulating film 126 may be sequentially formed in the word line trench 120T.

For example, the gate dielectric film 122 may be conformally arranged on the inner wall of the word line trench 120T. The gate electrode 124 may be formed by filling the word line trench 120T with a conductive layer (not illustrated), etching-back an upper portion of the conductive layer, and then exposing an upper portion of the word line trench 120T again. The capping insulating film 126 may be formed by filling a remaining portion of the word line trench 120T with an insulating material and planarizing the insulating material so that the upper surface of the buried insulating layer B12 is exposed.

Then, a portion of the buried insulating layer B12 that is on the upper surface of the substrate 110 may be removed, and the upper surface of the substrate 110 may be exposed. Thus, the gate dielectric layer 116 may be formed on the substrate 110 in the peripheral circuit area PCA.

While the gate dielectric layer 116 is formed, the portion of the buried insulating layer B12 that is on the upper surface of the substrate 110 may be removed, and the upper surface AC_U and the corner region AC_C of the second active area AC2 may be exposed. Accordingly, the gate dielectric layer 116 having excellent crystal quality may be formed on the second active area AC2.

Then, the buffer film 114 may be formed on the substrate 110 in the cell array area MCA.

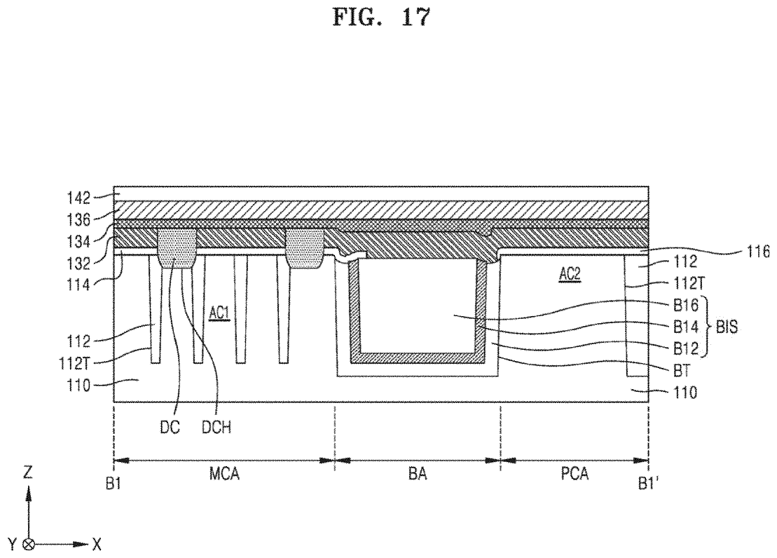

Referring to FIG. 17, the lower conductive layer 132 may be formed on the buffer film 114 and the gate dielectric layer 116. In some example embodiments, the lower conductive layer 132 may include Si, Ge, W, WN, Co, Ni, Al, Mo, Ru, Ti, TiN, Ta, TaN, Cu, or a combination thereof. For example, the lower conductive layer 132 may include polysilicon.

The direct contact hole DCH exposing the first active area AC1 of the substrate 110 may be formed by forming a mask pattern (not illustrated) on the lower conductive layer 132 and removing portions of the lower conductive layer 132 and the substrate 110 in the cell array area MCA. A conductive layer (not illustrated) may be formed in the direct contact hole DCH, and an upper portion of the conductive layer may be planarized so that the upper surface of the lower conductive layer 132 is exposed, thus forming the direct contact DC in the direct contact hole DCH.

Then, an intermediate conductive layer 134, an upper conductive layer 136, and a lower capping layer 142 may be sequentially formed on upper portions of the lower conductive layer 132 and the direct contact DC in the cell array area MCA and the peripheral circuit area PCA. The intermediate conductive layer 134 and the upper conductive layer 136 may each include TiN, TiSiN, W, tungsten silicide, or a combination thereof. The lower capping layer 142 may include silicon nitride.

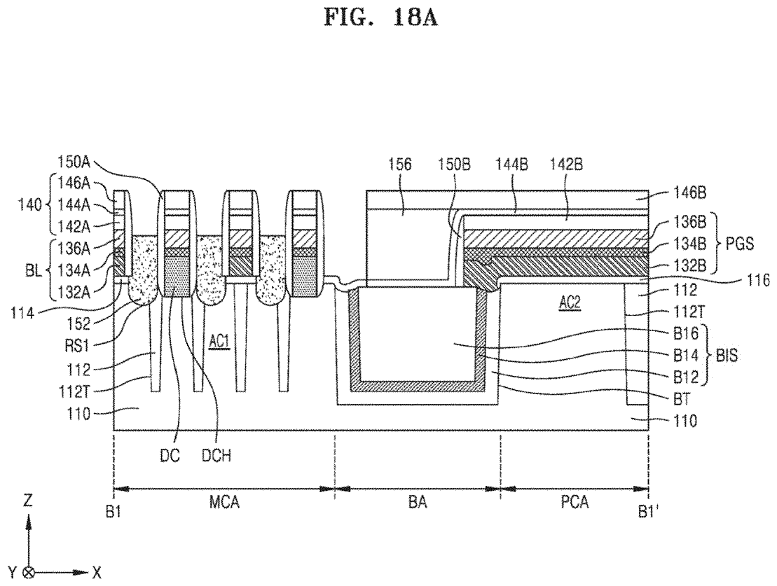

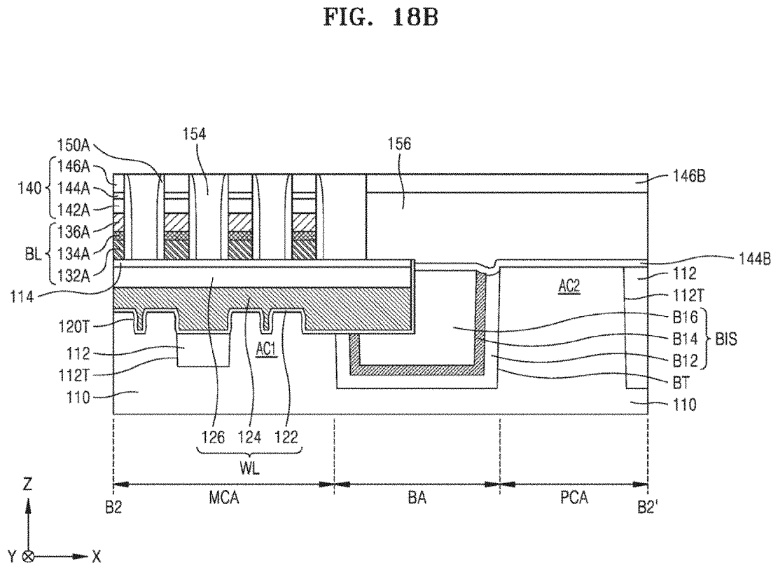

Referring to FIGS. 18A and 18B, the peripheral circuit gate electrode PGS, which includes the lower conductive pattern 132B, the intermediate conductive pattern 134B, and the upper conductive pattern 136B, and the gate capping pattern 142B covering the peripheral circuit gate electrode PGS may be formed on the gate dielectric layer 116 by patterning the gate dielectric layer 116, the lower conductive layer 132, the intermediate conductive layer 134, the upper conductive layer 136, and the lower capping layer 142 in the peripheral circuit area PCA while the cell array area MCA is covered by a mask pattern (not illustrated). Then, the insulating spacer 150B may be formed on both sidewalls of a stack structure including the gate dielectric layer 116, the peripheral circuit gate electrode PGS, and the gate capping pattern 142B.

Next, the lower capping layer 142 may be exposed in the cell array area MCA by removing the mask pattern covering the cell array area MCA. The protective layer 144, which covers the lower capping layer 142 in the cell array area MCA and covers the peripheral circuit gate electrode PGS and the insulating spacer 150B in the peripheral circuit area PCA, may be formed. Then, the first interlayer insulating film 156 filling space around the peripheral circuit gate electrode PGS is formed in the peripheral circuit area PCA.

An upper capping layer 146 is formed on the protective layer 144 in the peripheral circuit area PCA and the cell array area MCA.

The lower capping pattern 142A, the protective layer pattern 144A, and the upper capping pattern 146A, which are sequentially stacked on the upper conductive layer 136, are formed by forming the mask pattern M10 in the peripheral circuit area PCA and patterning the upper capping layer 146, the protective layer 144, and the lower capping layer 142 in the cell array area MCA. Here, the lower capping pattern 142A, the protective layer pattern 144A, and the upper capping pattern 146A are collectively referred to as an insulating capping structure 140.

The upper conductive layer 136, the intermediate conductive layer 134, and the lower conductive layer 132 may be etched by using the lower capping pattern 142A, the protective layer pattern 144A, and the upper capping pattern 146A as an etch mask in the cell array area MCA, and thus, the bit lines BL including the lower conductive pattern 132A, the intermediate conductive pattern 134A, and the upper conductive pattern 136A are formed.

In a process of forming the bit lines BL, a portion of the sidewall of the direct contact DC may be removed, and a portion of the direct contact hole DCH may be exposed.

In the cell array area MCA, the spacer 150A may be formed on the sidewalls of the bit line BL and the insulating capping structure 140, and the insulating fences 154 may be formed between corresponding pairs of the bit lines BL, respectively.

The recess spaces RS1 exposing the first active areas AC1 of the substrate 110 are formed between corresponding pairs of the bit lines BL, respectively, by removing a portion of the substrate 110 on the bottom of contact spaces (not illustrated) between the bit lines BL and the insulating fences 154. Then, the conductive plugs 152 filling the recess spaces RS1 and portions of the contact spaces respectively between corresponding pairs of the bit lines BL, are formed.

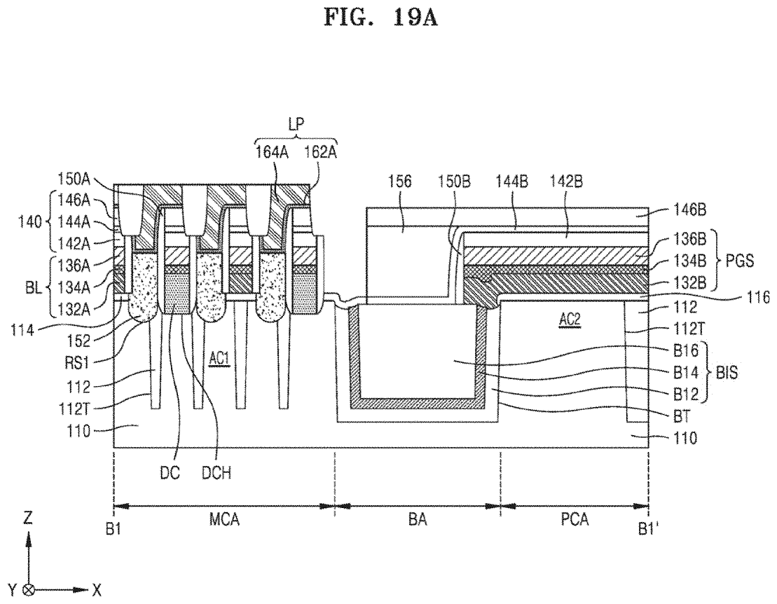

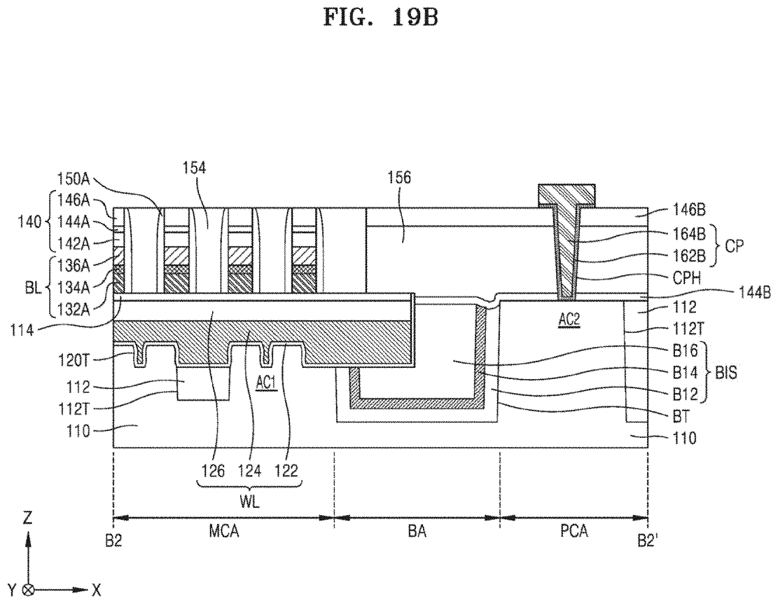

Referring to FIGS. 19A and 19B, the mask pattern is removed in the peripheral circuit area PCA, and the first interlayer insulating layer 156 is etched, thereby forming the contact holes CPH exposing the second active area AC2 of the substrate 110.

Then, a conductive barrier film 162 and a conductive layer 164 covering the exposed surface are formed on the substrate 110 in the cell array area MCA and the peripheral circuit area PCA.

Before the conductive barrier film 162 is formed, a metal silicide film (not illustrated) may be formed on the conductive plug 152 exposed through the contact spaces in the cell array area MCA, and the metal silicide film (not illustrated) may be formed on a surface of the second active area AC2 exposed through the contact holes CPH in the peripheral circuit area PCA.

The landing pads LP including the conductive barrier film 162A and the landing pad conductive layer 164A are formed in the cell array area MCA by patterning the conductive barrier film 162 and the conductive layer 164, and the contact plugs CP including the conductive barrier film 162B and the landing pad conductive layer 164B are formed in the peripheral circuit area PCA.

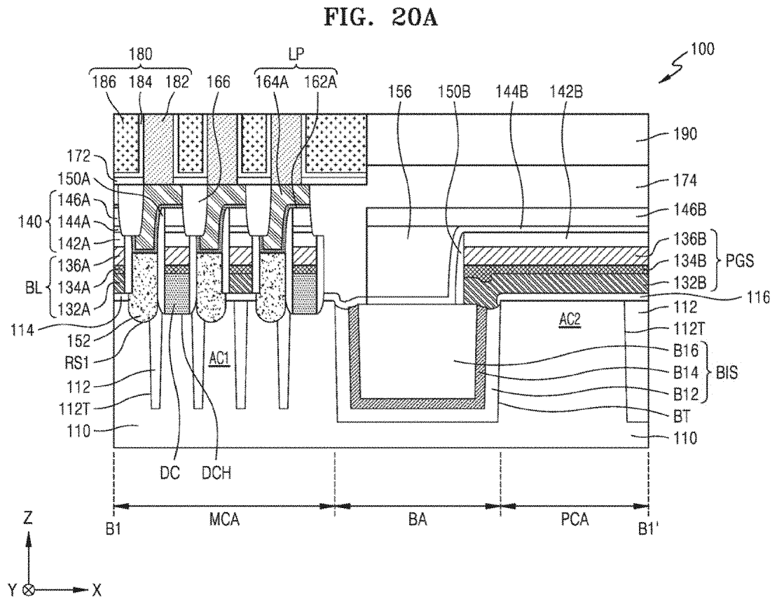

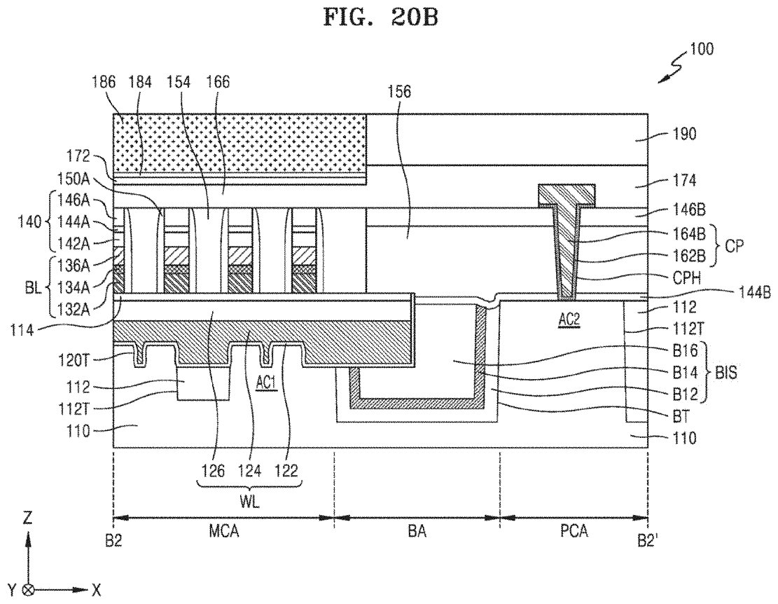

Referring to FIGS. 20A and 20B, the insulating pattern 166 covering the landing pads LP may be formed in the cell array area MCA, and the second etch stop layer 174 covering the contact plugs CP may be formed in the peripheral circuit area PCA.

Then, the first etch stop layer 172 may be formed in the cell array area MCA.

The lower electrodes 182 connected to the landing pads LP by penetrating the first etch stop layer 172 may be formed, and the capacitor dielectric layer 184 and the upper electrode 186 may be sequentially formed on the sidewalls of the lower electrodes 182.

Next, the second interlayer insulating layer 190 covering the upper electrode 186 may be formed in the cell array area MCA and the peripheral circuit area PCA.

The semiconductor device 100 may be completely manufactured by performing the above processes.

According to the above manufacturing method, the upper surface B12_U of the buried insulating layer B12 and the upper surface B14_U of the insulating liner B14 may be gently connected to each other without a steep inclination or a dramatic level difference as the first wet-etching process, the first strip process, the second wet-etching process, the second strip process, and the planarization process are sequentially performed. Accordingly, the generation of unetched regions and/or the discontinuity defects in the word lines WL may be mitigated or prevented in the process of forming the word line trench 120T.

In addition, as the first wet-etching process, the first strip process, the second wet-etching process, the second strip process, and the planarization process are sequentially performed, the upper surfaces B12_U and B14_U of the buried insulating layer B12 and the insulating liner B14 may be at a lower vertical level than the upper surface of the substrate 110, and the corner region AC_C and the upper surface AC_U of the second active area AC2 may not be covered by the buried insulating layer B12 and the insulating liner B14. Therefore, in the process of forming the gate dielectric layer 116, the gate dielectric layer 116 having improved crystal quality may be formed on the second active area AC2. The semiconductor device 100 may have great reliability.

While the inventive concepts have been particularly shown and described with reference to some example embodiments thereof, it will be understood that various changes in form and details may be made therein without departing from the spirit and scope of the following claims.

What is claimed is:

1. A semiconductor device comprising:
a substrate comprising a cell array area, a peripheral circuit area, and a boundary area between the cell array area and the peripheral circuit area;
a plurality of gate electrodes in the cell array area of the substrate, the plurality of gate electrodes being in a plurality of word line trenches that extend to an inside of the substrate;
a device isolation layer in the peripheral circuit area of the substrate, the device isolation layer defining a plurality of active areas; and
a boundary structure in the boundary area of the substrate, the boundary structure being in a boundary trench that extends to the inside of the substrate,
wherein the boundary structure includes,
a buried insulating layer on an inner wall of the boundary trench,
an insulating liner on the buried insulating layer, and
a gap-fill insulating layer on the insulating liner and filling an inside of the boundary trench, and
wherein an upper surface of the insulating liner is at a lower level than an upper surface of a corresponding one of the active areas.

2. The semiconductor device of claim 1, wherein
the insulating liner comprises,
a first sidewall contacting the buried insulating layer, and
a second sidewall contacting the gap-fill insulating layer, and
the upper surface of the insulating liner is inclined.

3. The semiconductor device of claim 2, wherein a first portion of the upper surface of the insulating liner that is adjacent to the first sidewall is at a lower vertical level than a second portion of the upper surface of the insulating liner that is adjacent to the second sidewall.

4. The semiconductor device of claim 1, wherein
the buried insulating layer comprises,
a first sidewall contacting a sidewall of the corresponding one of the active areas, and
a second sidewall contacting the insulating liner, and
an upper surface of the buried insulating layer is inclined.

5. The semiconductor device of claim 4, wherein a first portion of the upper surface of the buried insulating layer that is adjacent to the first sidewall of the buried insulating layer is at a higher vertical level than a second portion of the upper surface of the buried insulating layer that is adjacent to the second sidewall of the buried insulating layer.

6. The semiconductor device of claim 4, wherein a portion of the upper surface of the buried insulating layer that is adjacent to the first sidewall of the buried insulating layer is at a lower vertical level than the upper surface of the corresponding one of the active area.

7. The semiconductor device of claim 1, wherein the buried insulating layer and the gap-fill insulating layer each comprise silicon oxide, and the insulating liner comprises silicon nitride.

8. The semiconductor device of claim 1, wherein
at least one word line trench from among the word line trenches extends to an inside of the boundary area, and
a portion of the at least one word line trench is on the buried insulating layer and the insulating liner.

9. The semiconductor device of claim 8, wherein the portion of the at least one word line trench being on the buried insulating layer and the insulating liner has a flat bottom surface.

10. The semiconductor device of claim 1, further comprising:
a peripheral circuit transistor in an active area of the peripheral circuit area, from among the plurality of active areas, the peripheral circuit transistor comprising a gate dielectric layer on the active area, and
a gate electrode on the gate dielectric layer.

11. The semiconductor device of claim 10, wherein a portion of the gate dielectric layer covers a corner region of the active area that is at a boundary between the boundary area and the peripheral circuit area.

12. The semiconductor device of claim 11, wherein
an upper surface of the buried insulating layer is at a lower level than the upper surface of the active area, and
a portion of the gate dielectric layer covers the corner region of the active area and extends onto the upper surface of the buried insulating layer.

13. A semiconductor device comprising:
a substrate comprising a cell array area, a peripheral circuit area, and a boundary area between the cell array area and the peripheral circuit area;
a device isolation layer in the peripheral circuit area of the substrate, the device isolation layer defining a plurality of active areas;
a boundary structure in the boundary area of the substrate, the boundary structure being in a boundary trench that extends to an inside of the substrate, the boundary structure including a buried insulating layer on an inner wall of the boundary trench, an insulating liner on the buried insulating layer, and a gap-fill insulating layer on the insulating liner and filling an inside of the boundary trench; and
a plurality of gate electrodes in the cell array area of the substrate, the plurality of gate electrodes being in a plurality of word line trenches that extend to the inside of the substrate, the plurality of gate electrodes having respective end portions on the buried insulating layer and the insulating liner,
wherein an upper surface of the insulating liner is at a lower level than an upper surface of the active area.

14. The semiconductor device of claim 13, wherein
at least one word line trench from among the word line trenches extends to an inside of the boundary area, and
a portion of the at least one word line trench that is on the buried insulating layer and the insulating liner has a flat bottom surface.

15. The semiconductor device of claim 13, wherein
the insulating liner comprises,
a first sidewall contacting the buried insulating layer, and
a second sidewall contacting the gap-fill insulating layer, and
a first portion of the upper surface of the insulating liner that is adjacent to the first sidewall is at a lower vertical level than a second portion of the upper surface of the insulating liner that is adjacent to the second sidewall.

16. The semiconductor device of claim 13, wherein
the buried insulating layer comprises,
a first sidewall contacting a sidewall of a corresponding one of the active areas, and
a second sidewall contacting the insulating liner, and
a first portion of an upper surface of the buried insulating layer that is adjacent to the first sidewall of the buried insulating layer is at a higher vertical level than a second portion of the upper surface of the buried insulating layer that is adjacent to the second sidewall of the buried insulating layer.

17. The semiconductor device of claim 16, wherein the first portion of the upper surface of the buried insulating layer is at a lower vertical level than the upper surface of the corresponding one of the active areas.

18. A semiconductor device comprising:
a substrate comprising a cell array area, a peripheral circuit area, and a boundary area between the cell array area and the peripheral circuit area;
a device isolation layer in the peripheral circuit area of the substrate, the device isolation layer defining a plurality of active areas;
a boundary structure in the boundary area of the substrate, the boundary structure being in a boundary trench that extends to an inside of the substrate, the boundary structure including a buried insulating layer on an inner wall of the boundary trench, an insulating liner on the buried insulating layer, and a gap-fill insulating layer on the insulating liner and filling an inside of the boundary trench; and
a plurality of gate electrodes in the cell array area of the substrate, the plurality of gate electrodes being in a plurality of word line trenches that extend to the inside of the substrate, the plurality of gate electrodes having respective end portions on the buried insulating layer and the insulating liner,
wherein an upper surface of the buried insulating layer is at a lower level than an upper surface of the active area and does not cover a corner region of a corresponding one of the active areas.

19. The semiconductor device of claim 18, wherein
the buried insulating layer comprises,
a first sidewall contacting a sidewall of the corresponding one of the active areas, and
a second sidewall contacting the insulating liner, and
a first portion of the upper surface of the buried insulating layer that is adjacent to the first sidewall of the buried insulating layer is at a higher vertical level than a second portion of the upper surface of the buried insulating layer that is adjacent to the second sidewall of the buried insulating layer.

20. The semiconductor device of claim 18, wherein an upper surface of the insulating liner is at a lower level than the upper surface of the corresponding one of the active areas.
